(19) United States
(12) Patent Application Publication
(10) Pub. No.: US 2011/0057316 A1
(43) Pub. Date: Mar. 10, 2011

(54) COPPER WIRING LINE OF SEMICONDUCTOR DEVICE AND METHOD FOR FORMING THE SAME

(75) Inventors: Jae Hong KIM, Gyeonggi-do (KR); Sung Goon KANG, Seoul (KR); Won Kyu HAN, Seoul (KR); Soo Ho PARK, Busan Metropolitan City (KR)

(73) Assignees: Hynix Semiconductor Inc., Gyeonggi-do (KR); IUCF-HYU (Industry-University Cooperation Foundation Hanyang University), Seoul (KR)

(21) Appl. No.: 12/634,880

(22) Filed: Dec. 10, 2009

(30) Foreign Application Priority Data
Sep. 8, 2009 (KR) 10-2009-0084407

(51) Int. Cl. H01L 23/532; H01L 21/768

(52) U.S. Cl. 257/751; 438/653; 257/E23.161; 257/E21.584

(57) ABSTRACT

A copper wiring of a semiconductor device is which is resistant to unwanted diffusion of copper from away from the copper wiring is presented. The copper wiring includes an interlayer dielectric, a self-assembly monolayer, a plurality of catalyst particles, a metal layer, and a copper layer. The interlayer dielectric on the semiconductor substrate has a wiring forming region. The self-assembly monolayer is the wiring forming region. The plurality of catalyst particles are adsorbed onto the surface of the self-assembly monolayer. The metal layer is formed on the self-assembly monolayer which has the adsorbed catalyst particles such that the metal layer serves as both a seed layer and as a diffusion barrier. The copper layer substantially fills in the wiring forming region.

### CROSS-REFERENCE TO RELATED APPLICATIONS

The present application claims priority to Korean patent application number 10˜2009˜0084407 filed on Sep. 8, 2009, which is incorporated herein by reference in its entirety.

### BACKGROUND OF THE INVENTION

The present invention relates semiconductor devices and a methods for forming the same, and more particularly, to a copper wiring of a semiconductor device in which a wiring forming region can be completely filled with copper even though a line width decreases and a method for forming the same.

As is generally known in the art, increasing the speed of a CMOS (complementary metal oxide semiconductor) logic device mainly depends on reducing a gate delay time by decreasing the length of the gate. As high integration of semiconductor devices proceeds, RC (resistance capacitance) delays, brought about by physical phenomenon such as metallization at a back end of a line, can adversely influence logic device speeds.

In order to reduce RC delays, instead of using aluminum having specific resistance of 2.65 μΩcm, copper is thought to provide speed advantages because copper has a specific resistance of 1.7 μΩcm which is lower than that of aluminum. Furthermore, copper is considerably less prone to suffering from EM (electro migration) and SM (stress-induced migration) as compared to aluminum.

However, copper may suffer from a number of difficulties, such as, it is not easy to etch. Because of this fact, a damascene process is often used to form copper wirings. A method for forming a copper wiring using the damascene process will be briefly described below.

The damascene process usually involves forming an interlayer dielectric on a semiconductor substrate which is formed with an optional underlying structure. Afterwards a wiring forming region is defined by etching the interlayer dielectric. A diffusion barrier is then formed on the interlayer dielectric including the surface of the wiring forming region by using a PVD (physical vapor deposition) process, and in succession, a seed layer is formed on the diffusion barrier by using the same PVD process. A copper layer is then used to fill in the wiring forming region which already has the seed layer formed therein. This copper layer is usually performed using an electroplating process. Subsequently portions of the copper layer, the seed layer and the diffusion barrier, which are formed on the interlayer dielectric, are then removed. The diffusion barrier may be formed as a single layer using any one of Ta, TaN, Ti and TiN or a stack layer thereof.

However, as the line width of a copper wiring decreases, then the coverage of the seed layer formed by using the PVD process deteriorates on the sidewalls of the wiring forming region. Therefore, as a result of the deposition thickness of the seed layer decreasing on the sidewalls of the wiring forming region, then the specific resistance abruptly increases. Accordingly, it becomes more and more difficult, if not impossible, to completely fill the wiring forming region with copper when one attempts to electroplate copper into these areas with poor copper seed layer coverage.

Furthermore, as line widths decrease, then the proportion of the diffusion barrier in the wiring forming region increases. As a result the copper wiring resistance increases.

### BRIEF SUMMARY OF THE INVENTION

Embodiments of the present invention are directed to a copper wiring of a semiconductor device that can obviate the need for a separate diffusion barrier for preventing diffusion of copper and a method for forming the same.

Also, embodiments of the present invention are directed to a copper wiring of a semiconductor device that can omit formation of a diffusion barrier and thereby achieve greater filling of copper in the wiring forming regions.

Further, embodiments of the present invention are directed to a copper wiring of a semiconductor device that can reduce wiring resistance and a method for forming the same.

In one embodiment of the present invention, a copper wiring of a semiconductor device comprises an interlayer dielectric formed on a semiconductor substrate and having a wiring forming region; a self-assembly monolayer formed on a surface of the wiring forming region; a plurality of catalyst particles adsorbed to a surface of the self-assembly monolayer; a metal layer formed on the self-assembly monolayer including the catalyst particles and serving as a seed layer and a diffusion barrier; and a copper layer formed on the metal layer to fill the wiring forming region.

The self-assembly monolayer may be formed of a polar polymer which has surface polarity.

The polar polymer may include an amine group or a thiol group.

The catalyst particles may be formed of any one of Au, Ru, Pt, Ag, Pd, Ni, and mixtures thereof.

The catalyst particles may have a diameter of about 0.1˜10 nm.

The catalyst particles may be adsorbed at an interval of about 4˜8 nm.

The metal layer may comprise a ruthenium metal layer.

The ruthenium metal layer may be added with phosphorus (P).

The copper wiring may further comprise an auxiliary seed layer formed between the metal layer and the copper layer.

The auxiliary seed layer may be formed of copper.

The copper wiring may further comprise an auxiliary diffusion barrier formed between the metal layer and the copper layer.

The auxiliary diffusion barrier may comprise a metal oxide layer.

The metal oxide layer may comprise a ruthenium oxide layer.

In another embodiment of the present invention, a method for forming a copper wiring of a semiconductor device comprises the steps of forming an interlayer dielectric, having a wiring forming region, on a semiconductor substrate; forming a self-assembly monolayer on the interlayer dielectric including a surface of the wiring forming region; adsorbing catalyst particles to a surface of the self-assembly monolayer; forming a metal layer serving as a seed layer and a diffusion barrier, on the self-assembly monolayer including the catalyst particles; and forming a copper layer on the metal layer to fill the wiring forming region.

The step of forming the self-assembly monolayer may comprise the steps of dipping a resultant semiconductor substrate including the wiring forming region, into a chemical in which an organic solvent and a polar polymer having surface polarity are mixed; heating the resultant semiconductor substrate dipped into the chemical so that silanization reaction of the polar polymer occurs; cleaning a resultant semiconductor substrate so that reaction residues are removed; and baking a resultant cleaned semiconductor substrate.

The polar polymer may include an amine group or a thiol group. The polar polymer having the amine group or the thiol group may include 3-aminopropyltriethoxy-silane or 3-aminopropyltrimethoxy-silane.

The chemical may be prepared by mixing about 1 liter of an organic solvent with about 15˜35 grams of the polar polymer.

The silanization reaction of the polar polymer may be implemented by heating the polar polymer at a temperature of about 50˜70° C. for about 60˜400 minutes.

The cleaning step may be implemented using ethanol.

The baking step may be implemented in a vacuum oven at a temperature of about 100˜140° C. for about 3˜30 minutes.

The catalyst particles may be formed of any one of Au, Ru, Pt, Ag, Pd, Ni, and mixtures thereof.

The catalyst particles may have a diameter of about 0.1˜10 nm.

The step of adsorbing the catalyst particles may be implemented by dipping, for about 30˜600 minutes, the resultant semiconductor substrate formed with the self-assembly monolayer into a chemical bath suspending catalyst ion particles, and then reducing, using a reductant, the catalyst ion particles into the plated catalyst.

The reductant may comprise any one of hydrazine, NaBH₄, formaldehyde, and admixtures thereof.

In the step of adsorbing the catalyst ion particles, at least one of a pH and a temperature of the chemical, in which the catalyst ion particles are dispersed, may be changed such that an interval between the adsorbed catalyst particles is adjusted.

The pH of the chemical, in which the catalyst particles are dispersed, may be maintained between about 3˜6.

The temperature of the chemical bath, in which the catalyst ion particles are dispersed, may be maintained between about 50˜60° C.

The interval between the adsorbed catalyst particles may be adjusted to 4˜8 nm.

The metal layer may comprise a ruthenium layer.

The ruthenium layer may be added with phosphorus (P).

The ruthenium layer added with phosphorus (P) may be formed using an electroless plating technique.

The electroless plating may be performed by dipping the resultant semiconductor substrate adsorbed with the catalyst particles for 10˜300 seconds into a plating solution comprising ruthenium trihalide, sodium citrate, succinic acid and hypophosphite in which the hypophosphite acts as a reductant.

The plating solution may be aqueous and prepared by mixing about 2˜3 g of ruthenium trichloride (e.g., RuCl₃.XH₂O), about 3˜6 g/L of sodium citrate (e.g., Na₃C₆H₅O₇.2H₂O), about 0.5˜1 g/L of succinic acid (e.g., HO₂CCH.CHCO₂H), and about 0.001˜0.1 M of hypophosphite (e.g., NaH₂PO₂.H₂O). The pH of the plating solution may be adjusted to a pH of 10˜13, and the temperature of the plating solution may be maintained at 70˜90° C.

The ruthenium layer added with phosphorus (P) may be formed to a thickness of about 5˜20 nm.

After the step of forming the copper layer to fill the wiring forming region, the method may further comprise the step of removing portions of the copper layer, the metal layer, the catalyst particles and the self-assembly monolayer which are formed on the interlayer dielectric, such that the interlayer dielectric is exposed.

After the step of forming the metal layer and before the step of forming the copper layer to fill the wiring forming region, the method may further comprise the step of forming an auxiliary seed layer on the metal layer.

The auxiliary seed layer may be formed of copper.

After the step of forming the metal layer and before the step of forming the copper layer to fill the wiring forming region, the method may further comprise the step of forming an auxiliary diffusion barrier in a surface of the metal layer.

The step of forming the auxiliary diffusion barrier may be implemented by oxidating the surface of the metal layer and forming a metal oxide layer in the surface of the metal layer.

The metal oxide layer may comprise a ruthenium oxide layer.

### BRIEF DESCRIPTION OF THE DRAWINGS

FIG. 1 is a cross-sectional view showing a copper wiring of a semiconductor device in accordance with an embodiment of the present invention;

FIGS. 2A through 2E are sectional views showing the processes of a method for forming a copper wiring of a semiconductor device in accordance with another embodiment of the present invention;

FIG. 3 is a cross-sectional view showing a copper wiring of a semiconductor device in accordance with another embodiment of the present invention; and

FIG. 4 is a cross-sectional view showing a copper wiring of a semiconductor device in accordance with another embodiment of the present invention.

### DESCRIPTION OF SPECIFIC EMBODIMENTS

It is understood herein that the drawings are not necessarily to scale and in some instances proportions may have been exaggerated in order to more clearly depict certain features of the invention.

In the present invention, when forming a copper wiring, a ruthenium layer is formed on the surface of a wiring forming region by using self-assembly techniques and electroless plating methods.

The ruthenium layer not only serve as a seed layer when plating copper but also serve as a diffusion barrier in a completely formed copper wiring. Preferably, the ruthenium layer is added with phosphorus (P).

In detail, since the ruthenium layer has low specific resistance of 7 μΩcm, copper plating can be directly conducted. That is to say, the ruthenium layer can be used as a seed layer when plating copper.

While it is known that the ruthenium layer can prevent or is at least inhibit copper diffusion at temperatures lower than a room temperature, it is also known that ruthenium cannot completely prevent diffusion of copper at the room temperature due to the fact that ruthenium has a columnar structure. In order to cope with this problem, a method of forming a ruthenium layer having an amorphous structure. The ruthenium layer having the amorphous structure can be formed by adding phosphorus (P) as a second element. The ruthenium layer having the amorphous structure formed in this way exhibits excellent diffusion barrier characteristics as compared to a ruthenium layer having the same thickness formed by using a more conventional PVD process.

In the present invention the ruthenium layer added with phosphorus (P) and having the amorphous structure is formed using an electroless plating process. Electroless plating is a method in which a metal layer is formed without the need for electrodes by using solution reduction-oxidation (redox) chemical reactions. Electroless plating provides a number of advantages in that an impurity content in the metal layer is low and no expensive equipment is not needed as compared to CVD or PVD processes.

Therefore, by forming the ruthenium layer added with phosphorus (P) and having the amorphous structure by using electroless plating techniques, a ruthenium layer using added phosphorus (P) to form a seed layer for plating copper as well as forming a diffusion barrier for plated copper.

When plating copper in the wiring forming region, in order to suppress or minimize the occurrence of voids and seams in the wiring forming region, it is necessary to form a seed layer as a thin layer having a substantially uniform thickness. In this regard, in order to form the seed layer as a thin layer having a uniform thickness, self-assembly technology is employed.

In the self-assembly technology, after forming a self-assembly monolayer of adsorbed catalyst particles onto the surface of the wiring forming region at an interval of 4˜8 nm, a metal layer can be formed on the self-assembly monolayer of the catalyst particles. The resultant metal layer can have a substantially uniform thickness of no greater than 20 nm. The adsorbed catalyst particles preferably have an average diameter of about 2˜3 nm. Accordingly, the resultant ruthenium layer formed can be a thin layer having a uniform thickness and which has an amorphous structure brought about by added phosphorus (P) when forming the resultant ruthenium layer via the self-assembly technology. When subsequently plating copper, copper can substantially fill in the wiring forming region which prevents or minimizes the occurrence of voids and seams in the resultant copper wire.

As a result, the ruthenium layer made by adding phosphorus (P) during the electroless plating self-assembly technique results in producing a thin layer of amorphous ruthenium that also has a relatively uniform thickness. The resultant ruthenium layer made by added phosphorus (P) can be used as both a seed layer for plating copper as well as used as a diffusion barrier for the resultant copper wiring.

As a consequence, one can omit the formation of a separately distinct diffusion barrier. That is, after forming amorphous ruthenium layer, one can immediately proceed to the step of filling the wiring forming region with copper which prevents or minimizes the occurrence of voids and seams in the wiring forming region. Accordingly, a copper wiring having high reliability can be realized by using electroless plating. Hence, the resultant electroless plated copper wiring can be reliably formed at a reduced cost in a pattern below 20 nm.

Hereafter, specific embodiments of the present invention will be described in detail with reference to the accompanying drawings.

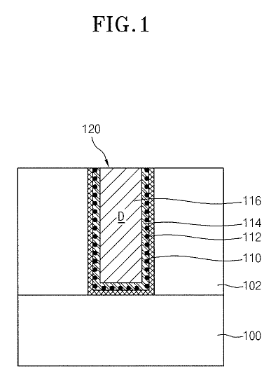

FIG. 1 is a cross-sectional view showing a copper wiring of a semiconductor device in accordance with an embodiment of the present invention.

Referring to FIG. 1, an interlayer dielectric 102 having a wiring forming region D is formed on a semiconductor substrate 100, and a copper wiring 120 is formed by filling in the wiring forming region D. The semiconductor substrate 100 is understood to be any type of semiconductor substrate that can also have any number of predetermined underlying structures (not shown) which can include transistors, capacitors, diodes, wires and electrical vias (all not shown). The copper wiring 120 includes a self-assembly monolayer 110, catalyst particles 112, a ruthenium layer 114 and a copper layer 116. The self-assembly monolayer 110 is formed on the surface of the wiring forming region D. The catalyst particles 112 are adsorbed onto the surface of the self-assembly monolayer 110. The ruthenium layer 114 is formed on the self-assembly monolayer 110 having the adsorbed catalyst particles 112. The ruthenium layer 114 with the adsorbed catalyst particles is thought to serve as a seed layer and as a diffusion barrier. The copper layer 116 is formed on the ruthenium layer 114 to completely or at least substantially fill in the wiring forming region D.

The self-assembly monolayer 110 has surface polarity on the surface thereof. In other words, the surface of the self-assembly monolayer 110 is composed of a polar polymer having positive and negative polarities. The self-assembly monolayer 110, for example, can be an amine group or a thiol group in which both groups are compatible with noble metals such as Pt, Au, Ru, Ag and Ni.

The catalyst particles 112 comprise particles of any one of Au, Ag, Ru, Pd, Pt, Ni, and admixture thereof. The catalyst particles 112 are preferred to an average diameter of about 0.1˜10 nm. The catalyst particles 112 are adsorbed onto the surface of the self-assembly monolayer 110 preferably along an average neighboring interval of about 4˜8 nm.

The ruthenium layer 114 serves as both a seed layer and as a diffusion barrier, and has a relatively low specific resistance of 7 μΩcm. The ruthenium layer 114 is formed on the self-assembly monolayer 110 and on the catalyst particles 112. Preferably the resultant ruthenium layer 114 is a thin layer having a relatively uniform thickness of about 5˜20 nm. In particular, the ruthenium layer 114 has an amorphous structure brought about by adding with phosphorus (P) during the electroless fabrication process.

The copper layer 116 is also formed using another electroless plating technique. The copper layer 116 is electroless plating onto the ruthenium layer 114 that serves as a seed layer for the electroplating. The resultant copper layer 116 substantially fills in the wiring forming region D while minimizing the generation of voids and seams along the wiring forming region D.

In the copper wiring of a semiconductor device in accordance with one embodiment, the ruthenium layer is formed as a thin layer having a uniform thickness by using a self-assembly technology. This thin and uniform thickness ruthenium layer made to by added with phosphorus (P) results in having an amorphous structure. In addition, due to the fact that the resultant ruthenium layer can function as a diffusion barrier then there is no need for a separate diffusion barrier. As a result gapfill characteristics for the wiring forming region can be improved by using this amorphous ruthenium layer. Also the resultant copper wiring made by this method exhibits an improved reliability which necessarily improves the reliability of the semiconductor device having the resultant copper wiring.

While the above embodiments employ the ruthenium made by added phosphorus (P) to produce the amorphous ruthenium layer 124, it is understood herein that other materials can be used in the present invention that also serve as both the seed layer for plating copper and serve as a diffusion barrier in a completed copper wiring. That is, it is readily understood that any number of alternate metals can be used to serve as a seed layer and as the diffusion barrier. Preferably these alternate metals should have a low specific resistance properties which allow direct plating and should be able to inhibits copper diffusion. Of course, another conductive layer can be used instead of the metal layer.

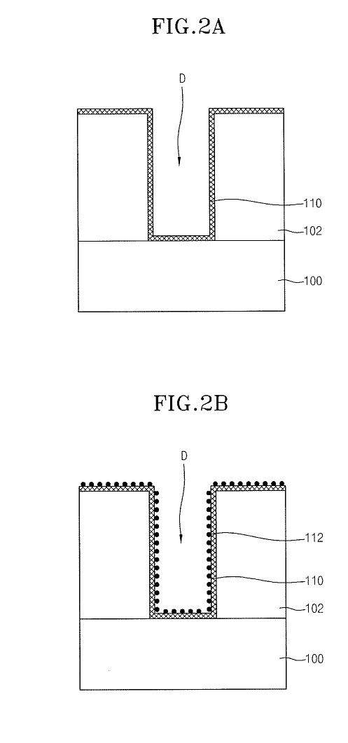

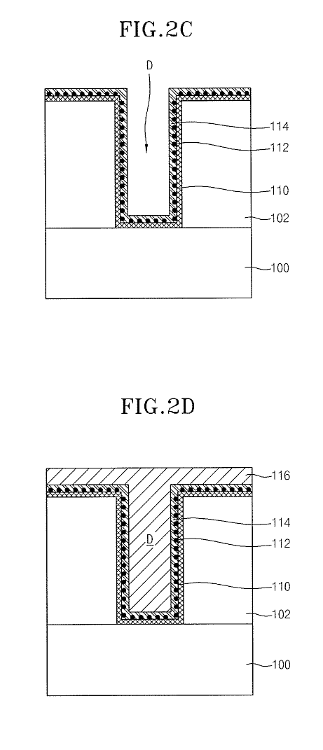

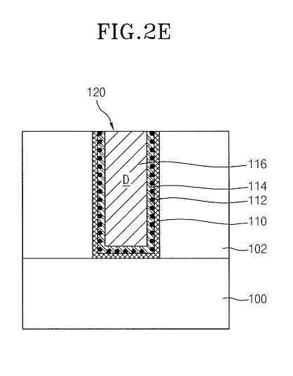

FIGS. 2A through 2E are sectional views depicting some of the more important processes of the method for forming a copper wiring of a semiconductor device in accordance with another embodiment of the present invention. The method will be described below.

Referring to FIG. 2A, after forming an interlayer dielectric 102 on a semiconductor substrate 100 which is formed with a predetermined underlying structure, a wiring forming region D is defined in the interlayer dielectric 102 by using a damascene process. The wiring forming region D is defined in the form of a trench by using a single damascene process. The wiring forming region D may be formed using a dual damascene process, and in this case, the wiring forming region D is defined in a form that includes a via hole and a trench placed on the via hole.

A self-assembly monolayer 110, which comprises a polar polymer having surface charges, that is, plus or minus polarity, is formed on the interlayer dielectric 102 including the surface of the wiring forming region D. It is important to note that the monolayer 110 might not necessarily be a layer composed of a single molecular layer but rather it is understood herein that the monolayer 110 can comprise a single molecular layer as well as multiple molecular layers. The polar polymer includes an amine group or a thiol group which are compatible with metals such as those selected from the group consisting of Pt, Au, Ru, Ag, Ni and mixtures thereof. For example, one preferred method of forming the self-assembly monolayer 110 is to dip the semiconductor substrate 100 having the wiring forming region D into a chemical bath which is prepared preferably made up by mixing 1 liter of an to organic solvent, such as ethanol or toluene, with about 15˜35 g, preferably, 25 g of 3-aminopropyltriethoxy-silane or 3-aminopropyltrimethoxy-silane. After heating the temperature of the chemical bath to about 50˜70° C. for about 60˜400 minutes, preferably, at the temperature of about 60° C., then the semiconductor substrate 100 having the wiring forming region D is immerged into the warmed chemical bath for about 180 minutes.

After removing the semiconductor substrate 100 having the wiring forming region D from the warmed chemical bath, then the resultant semiconductor substrate 100 formed with the self-assembly monolayer 110 is cleaned using ethanol to remove reaction residues. Afterwards, in order to stabilize the bonding structure of the self-assembly monolayer 110, the resultant cleaned semiconductor substrate 100 is baked in a vacuum oven at a temperature of about 100˜140° C. for about 3˜30 minutes, preferably, at the temperature of about 120° C. for about 5 minutes.

Referring to FIG. 2B, the resultant semiconductor substrate 100 formed with the self-assembly monolayer 110 is then immerged into a solution containing catalyst ion particles for about 60˜400 minutes. This exposure to the solution containing catalyst ion particles results in the catalyst particles 112 being adsorbed onto the surface of the self-assembly monolayer 110. The catalyst particles 112 comprise ions of any one of Au, Ru, Pt, Ag, Pd, Ni and mixtures thereof and these catalyst particles 112 preferably have an average mean diameter of about of 0.1˜10 nm.

The catalyst particles 112 are adsorbed onto the surface of the self-assembly monolayer 110 by dipping the resultant semiconductor substrate 100 formed with the self-assembly monolayer 110 in a chemical solution containing ions of Au, Ru, Pt, Ag, Pd or Ni, maintaining the semiconductor substrate 100 in the catalyst chemical solution for about 30˜600 minutes, and subsequently reducing the ions using a reductant such as hydrazine, NaBH₄ or formaldehyde.

When adsorbing the catalyst particles 112 it is preferable that the adsorbed catalyst particles 112 are spaced at an average distance from each other at about 4˜8 nm. Preferably, in one embodiment of the present invention, the pH and the temperature of the chemical bath, in which the catalyst particles are dispersed, are regulated to a pH of about 3˜6 and a temperature of about 50˜60° C.

Referring to FIG. 2C, an electroless plating technique is used to add a metal layer, for example, a ruthenium layer 114 added with phosphorus (P), onto the self-assembly monolayer 110 which already has the adsorbed catalyst particles 112. The formation of the ruthenium layer 114 added with phosphorus (P) is conducted by dipping the resultant semiconductor substrate 100 having the adsorbed catalyst particles 112 for about 10˜300 seconds in a plating solution. The plating solution may be any ruthenium bearing plating solution in which it is preferable that the plating solution contains about 2˜3 g of ruthenium trichloride (e.g., RuCl₃.XH₂O), about 3˜6 g/L of sodium citrate (e.g., Na₃C₆H₅O₇.2H₂O), about 0.5˜1 g/L of succinic acid (e.g., HO₂CCH.CHCO₂H), and about 0.001˜0.1 M of hypophosphite (e.g., NaH₂PO₂.H₂O) as a reductant are mixed, of which pH is regulated to 10˜13, and of which temperature is maintained at about 70˜90° C. The ruthenium layer 114 added with phosphorus (P) is preferably formed to a thickness of 5˜20 nm. In order to improve diffusion barrier capability for copper, the amount of hypophosphite as a reductant adjusted within a range of about 0.001˜0.1 M such that the amount of phosphorus (P) added in the ruthenium layer 114 is controlled.

Due to the fact that the ruthenium layer 114 is added with phosphorus (P) using electroless plating onto the self-assembly monolayer 110 which includes the catalyst particles 112, then the ruthenium layer 114 can be precisely formed as a thin layer having a substantially uniform thickness of about 5˜20 nm. Also, due to the fact that phosphorus (P) is added in the ruthenium layer 114, the ruthenium layer 114 is formed to have an amorphous structure. Hence, the ruthenium layer 114 according to one embodiment of the present invention acts as an excellent diffusion barrier with respect to inhibiting copper diffusion. As a consequence, in the embodiment of the present invention, it is not necessary to form a separate diffusion barrier after forming the ruthenium layer 114.

While the ruthenium layer 114 is formed in one embodiment of the present invention as a material layer that serves as both a seed layer for plating copper and serves as a diffusion barrier in a copper wiring, it is understood herein that the present is invention is not to be limiting to the illustrative example of ruthenium with phosphorous. Rather the metal layer is understood to be encompass any number of other alternate elemental compositions which can also be used to produce the metal layer or conductive layer capable of serving as a seed layer when plating copper and as a diffusion barrier in a copper wiring can be formed instead of the ruthenium layer.

Referring to FIG. 2D, a copper layer 116 is formed on the ruthenium layer 114 using the ruthenium layer 114 as a seed layer in such a way as to completely fill the wiring forming region D. The formation of the copper layer 116 can be preformed by using either electroless plating or electroplating techniques.

For example, the copper layer 116 can be also be successively formed using electroless plating onto the ruthenium layer 114 which substantially fills in the wiring forming region D. Accordingly, using the electroless plating the copper layer 116 is formed by dipping the resultant semiconductor substrate 100 formed with the ruthenium layer 114 into an electroless copper plating solution for about 10˜120 seconds. The electroless copper plating solution can be any type of electroless copper plating solution. One preferred embodiment of the electroless copper plating solution is that is comprises about 0.04 M of copper II sulfate, 0.08 M of ethylenediamine tetraacetic acid (EDTA), 0.08M of glyoxylic acid, and 1 ppm of PEG4000 (polyethylene glycol 4000), in which the pH is regulated between about 10˜14, preferably at a pH of 12.6. The temperature of the electroless copper plating solution is maintained at about 60˜80° C., preferably 70° C. when performing the electroless plating operation.

Alternately the formation of copper layer 116 can be achieved using an electro copper plating solution which is prepared by mixing 0.26 M of copper II sulfate, 2.00 M of H₂SO₄, 50 ppm of HCl, 100 ppm of PEG2000 (polyethylene glycol 2000), and 1000 ppm of SPS (bis-sodium sulfopropyl disulfide) and maintaining the temperature at about room temperature. In this embodiment the electroplating of the copper layer 116 is preferably conducted for several minutes at a condition of 0.005˜0.02 A/cm².

In the embodiment of the present invention, since the ruthenium layer 114 to be used as a seed layer is formed as a thin layer of a uniform thickness, then filling of the copper layer 116 into the wiring forming region D can be implemented substantially perfectly without generation of voids or seams. In particular, in the embodiment of the present invention, because a separate diffusion barrier is not additionally formed after forming the seed layer, the width of the wiring forming region D to be filled with the copper layer 116 can be increased by the thickness of the omitted diffusion barrier, by which the substantially perfect filling of the copper layer 116 into the wiring forming region D without generation of voids or seams can be effectively implemented.

Referring to FIG. 2E, portions of the copper layer 116, the ruthenium layer 114, the catalyst particles 112 and the self-assembly monolayer 110, which are formed on the interlayer dielectric 102, are removed, for example, by using a CMP (chemical mechanical polishing) process, such that the interlayer dielectric 102 is exposed. By doing this, the copper wiring 120 according to the embodiment of the present invention is formed in the wiring forming region D. While the ruthenium layer 114 serves as a seed layer while forming the copper wiring 120, it also serves as a diffusion barrier for preventing diffusion of copper in the completely formed copper wiring 120 because it has an amorphous crystalline structure which is thought to be brought about by the added phosphorus (P) in the ruthenium layer 114.

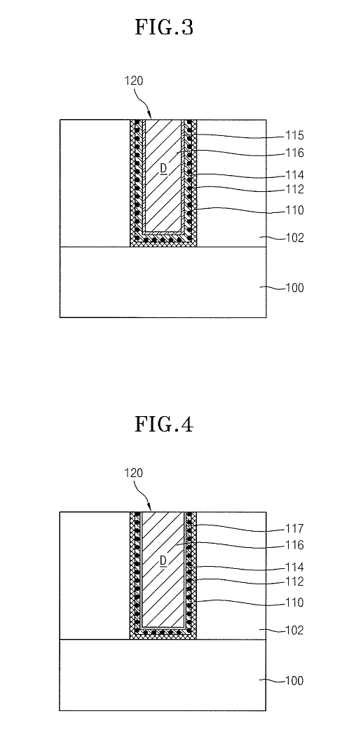

FIG. 3 is a cross-sectional view showing a copper wiring of a semiconductor device in accordance with another embodiment of the present invention.

Referring to FIG. 3, an auxiliary seed layer 115 is additionally formed between the ruthenium layer 114 and the copper layer 116. The auxiliary seed layer 115 is formed to improve electrical conductivity, and is preferably made of copper. The auxiliary seed layer 115 is formed on the surface of the ruthenium layer 114 to a thickness of about 200˜300 Å by using a PVD (physical vapor deposition) process after the ruthenium layer 114 is formed by using electroless plating.

In the embodiment of the present invention, by forming the auxiliary seed layer 115, it is possible to substantially prevent a filling rate of copper from decreasing due to increase in resistance when subsequently plating copper.

Another metal layer can be formed as the auxiliary seed layer 115 instead of the copper layer.

FIG. 4 is a cross-sectional view showing a copper wiring of a semiconductor device in accordance with another embodiment of the present invention.

Referring to FIG. 4, an auxiliary diffusion barrier 117 is additionally formed between the ruthenium layer 114 and the copper layer 116. The auxiliary diffusion barrier 117 is formed to prevent copper from diffusing to the interlayer dielectric 102 made of a low dielectric constant material. The auxiliary diffusion barrier 117 is formed in the surface of the ruthenium layer 114 by oxidating the surface of the ruthenium layer 114 after forming the ruthenium layer 114 by using electroless plating. Preferably, the ruthenium oxide layer 117 is formed to a thickness of about 1˜3 nm by using an oxidation process at a temperature of between about 200˜700° C.

In the embodiment of the present invention, since a diffusion barrier is composed of the stack of the ruthenium layer 114 having the amorphous structure by being added with phosphorus (P) and the ruthenium oxide layer 117, diffusion barrier capability for copper in the copper wiring having the diffusion barrier composed of the stack can be further improved.

Meanwhile, it is understood that another metal oxide layer can be formed as the auxiliary diffusion barrier instead of the ruthenium oxide layer.

In FIGS. 3 and 4, the other constructions excluding the additional formation of the auxiliary seed layer and the auxiliary diffusion barrier are the same as those of the aforementioned embodiment of the present invention, detailed descriptions thereof will be omitted herein.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A copper wiring of a semiconductor device comprising:
an interlayer dielectric formed on a semiconductor substrate, wherein the interlayer dielectric has a wiring forming region;
a self-assembly monolayer formed on a surface of the wiring forming region;
a plurality of catalyst particles adsorbed onto the surface of the self-assembly monolayer;
a metal layer formed on the self-assembly monolayer having the adsorbed catalyst particles, wherein the metal layer serves as a seed layer and as a diffusion barrier; and
a copper layer formed on the metal layer, wherein the copper layer substantially fills in the wiring forming region.

2. The copper wiring according to claim 1, wherein the self-assembly monolayer comprises a polar polymer.

3. The copper wiring according to claim 2, wherein the polar polymer includes an amine group or a thiol group.

4. The copper wiring according to claim 1, wherein the catalyst particles are formed of any one of Au, Ru, Pt, Ag, Pd and Ni.

5. The copper wiring according to claim 1, wherein the catalyst particles have an average diameter of about 0.1˜10 nm.

6. The copper wiring according to claim 1, wherein the catalyst particles are adsorbed onto the surface of the self-assembly monolayer at an average neighboring distance of about 4˜8 nm.

7. The copper wiring according to claim 1, wherein the metal layer comprises a ruthenium layer.

8. The copper wiring according to claim 7, wherein the ruthenium layer is added with phosphorus (P) such that the ruthenium layer with the added phosphorus (P) has an amorphous crystalline structure.

9. The copper wiring according to claim 1, further comprising an auxiliary seed layer formed between the metal layer and the copper layer.

10. The copper wiring according to claim 9, wherein the auxiliary seed layer is formed of copper.

11. The copper wiring according to claim 1, further comprising an auxiliary diffusion barrier formed between the metal layer and the copper layer.

12. The copper wiring according to claim 11, wherein the auxiliary diffusion barrier comprises a metal oxide layer.

13. The copper wiring according to claim 12, wherein the metal oxide layer comprises a ruthenium oxide layer.

14. A method for forming a copper wiring of a semiconductor device, comprising the steps of:
forming an interlayer dielectric having a wiring forming region onto a semiconductor substrate;
forming a self-assembly monolayer onto the wiring forming region of the interlayer dielectric;
adsorbing catalyst particles onto the self-assembly monolayer;
forming a metal layer onto the self-assembly monolayer having the adsorbed catalyst particles; and
forming a copper layer on the metal layer such that the copper layer substantially fills in the wiring forming region.

15. The method according to claim 14, wherein the step of forming the self-assembly monolayer comprises the steps of:
dipping the semiconductor substrate having the wiring forming region into a chemical bath, the chemical bath comprising an organic solvent and a polar polymer;
heating the semiconductor substrate dipped into the chemical bath to promote a silanization reaction of the polar polymer to occur;
cleaning the semiconductor substrate after heating the semiconductor substrate to substantially remove any reaction residues from the semiconductor substrate; and
baking the cleaned semiconductor substrate.

16. The method according to claim 15, wherein the polar polymer includes an amine group or a thiol group.

17. The method according to claim 16, wherein the polar polymer is having the amine group or the thiol group includes 3-aminopropyltriethoxy-silane or 3-aminopropyltrimethoxy-silane.

18. The method according to claim 15, wherein the chemical bath is comprises a mixture of about 1 liter of an organic solvent and about 15˜35 g of the polar polymer.

19. The method according to claim 15, wherein the silanization reaction of the polar polymer is promoted by heating the polar polymer at a temperature of about 50˜70° C. for about 60˜400 minutes.

20. The method according to claim 15, wherein the cleaning step is implemented using ethanol as a wash.

21. The method according to claim 15, wherein the baking step is performed in a vacuum oven at a temperature of about 100˜140° C. for about 3˜30 minutes.

22. The method according to claim 14, wherein the catalyst particles are composed of any one of Au, Ru, Pt, Ag, Pd, Ni and mixtures thereof.

23. The method according to claim 14, wherein the catalyst particles have an average diameter of about 0.1˜10 nm.

24. The method according to claim 14, wherein the step of adsorbing the catalyst particles comprises:
dipping the semiconductor substrate formed with the self-assembly monolayer into a chemical solution for about 30˜600 minutes in which the catalyst particles are suspended in the chemical solution and the catalyst particles are in an ionized state; and
reducing the catalyst particles in the ionized state using a reductant.

25. The method according to claim 24, wherein the reductant comprises any one of hydrazine, NaBH₄ and formaldehyde.

26. The method according to claim 24, wherein in the step of adsorbing the catalyst particles at least one of a pH and a temperature of the chemical, in which the catalyst particles are dispersed, is changed such that an interval between the adsorbed catalyst particles is adjusted.

27. The method according to claim 26, wherein the pH of the chemical, in which the catalyst particles are dispersed, is regulated between about a pH of 3˜6.

28. The method according to claim 26, wherein the temperature of the chemical, in which the catalyst particles are dispersed, is regulated between about 50˜60° C.

29. The method according to claim 26, wherein an average neighboring distance between the adsorbed catalyst particles is adjusted to about 4˜8 nm.

30. The method according to claim 14, wherein the metal layer comprises a ruthenium layer.

31. The method according to claim 30, wherein the ruthenium layer is added with phosphorus (P) to form an amorphous crystalline structure of the ruthenium layer.

32. The method according to claim 31, wherein the ruthenium layer added with phosphorus (P) is formed by using electroless plating.

33. The method according to claim 32, wherein the electroless plating is conducted by dipping a resultant semiconductor substrate adsorbed with the catalyst particles for 10˜300 seconds in a plating solution comprises ruthenium trichloride, sodium citrate, succinic acid and sodium hypophosphite.

34. The method according to claim 33, wherein the plating solution is an aqueous plating solution comprising about 2˜3 g/L of the ruthenium trichloride, about 3˜6 g/L of the sodium citrate, about 0.5˜1 g/L of the succinic acid, and 0.001˜0.1 M of sodium hypophosphite, in which the pH of the aqueous plating solution is regulated between about a pH of 10˜13, and a temperature of the plating solution is maintained at about 70˜90° C.

35. The method according to claim 31, wherein the ruthenium layer added with phosphorus (P) is formed to a thickness of about 5˜20 nm.

36. The method according to claim 14 further comprises the step of removing portions of the copper layer, the metal layer, the catalyst particles and the self-assembly monolayer which are formed on the interlayer dielectric so that the interlayer dielectric is exposed wherein the removing step is wherein performed after the step of forming the copper layer.

37. The method according to claim 14 further comprises the step of forming an auxiliary seed layer on the metal layer, wherein the step of forming the auxiliary seed layer is performed after the step of forming the metal layer and before the step of forming the copper layer.

38. The method according to claim 35, wherein the auxiliary seed layer is formed of copper.

39. The method according to claim 14 further comprises the step of forming an auxiliary diffusion barrier in a surface of the metal layer, wherein the step of forming an auxiliary diffusion barrier is performed after the step of forming the metal layer and before the step of forming the copper.

40. The method according to claim 39, wherein the step of forming the auxiliary diffusion barrier is implemented by oxidating the surface of the metal layer and forming a metal oxide layer in the surface of the metal layer.

41. The method according to claim 40, wherein the metal oxide layer comprises a ruthenium oxide layer.
